(19) United States
(12) Patent Application Publication
(10) Pub. No.: US 2016/0041479 A1
(43) Pub. Date: Feb. 11, 2016

(54) FOCUS CORRECTION METHOD, FOCUS CORRECTION APPARATUS AND NON-TRANSITORY COMPUTER-READABLE RECORDING MEDIUM

(71) Applicant: KABUSHIKI KAISHA TOSHIBA, Minato-ku (JP)

(72) Inventor: Hiroyuki TANIZAKI, Yokkaichi (JP)

(73) Assignee: KABUSHIKI KAISHA TOSHIBA, Minato-ku (JP)

(21) Appl. No.: 14/750,388

(22) Filed: Jun. 25, 2015

Related U.S. Application Data
(60) Provisional application No. 62/034,421, filed on Aug. 7, 2014.

(51) Int. Cl. G03F 7/20; G01B 11/14

(52) U.S. Cl. CPC G03F 7/70641; G01B 11/14

(57) ABSTRACT

In accordance with an embodiment, a focus correction method includes obtaining a first defocus amount by measuring a QC wafer, obtaining a second defocus amount by measuring a product wafer, generating high-order focus correction data for an entire wafer surface by interpolating the second defocus amount on the basis of the first defocus amount, and correcting a focus on the basis of the high-order focus correction data.

### CROSS REFERENCE TO RELATED APPLICATIONS

This application is based upon and claims the benefit of U.S. provisional Application No. 62/034,421, filed on Aug. 7, 2014, the entire contents of which are incorporated herein by reference.

### FIELD

Embodiments described herein relate generally to a focus correction method, a focus correction apparatus, and a non-transitory computer-readable recording medium.

### BACKGROUND

In manufacture a semiconductor integrated circuit device, not only critical dimension (CD) management in a photolithographic process but also focus management of exposure light is important to form a micropattern with precision.

However, a focus position may vary due to change of control parameters for an exposure apparatus with time due to a continuous use of the exposure apparatus, thus a technique for accurately correcting such a focus variation has been required.

### BRIEF DESCRIPTION OF THE DRAWINGS

In the accompanying drawings:

FIG. 1 is a flowchart showing a general procedure of a focus correction method according to one embodiment; and

FIG. 2 is a block diagram showing the general configuration of a focus correction apparatus according to one embodiment.

### DETAILED DESCRIPTION

In accordance with an embodiment, a focus correction method includes obtaining a first defocus amount by measuring a QC wafer, obtaining a second defocus amount by measuring a product wafer, generating high-order focus correction data for an entire wafer surface by interpolating the second defocus amount on the basis of the first defocus amount, and correcting a focus on the basis of the high-order focus correction data.

Embodiments will now be explained with reference to the accompanying drawings. Like components are provided with like reference signs throughout the drawings and repeated descriptions thereof are appropriately omitted. In the following explanation, a “product mask” refers to a mask used to manufacture a product device in a semiconductor production line, and a “QC” mask refers to a dummy mask which is other than the product mask and which is produced for the management of an exposure apparatus. A “product wafer” refers to a wafer used to manufacture a product device in a semiconductor production line, and a “QC wafer” refers to a dummy wafer which is other than the product wafer and which is produced for the management of the exposure apparatus. Moreover, “high order” refers to being represented by a high-order function of a second or higher order.

(1) Focus Correction Method

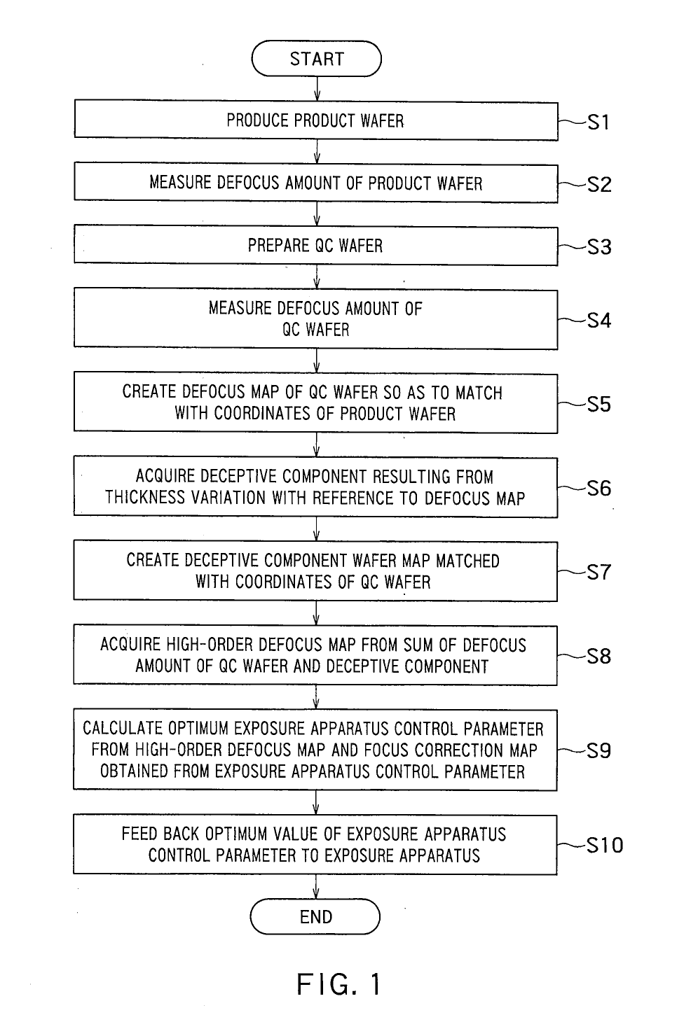

A focus correction method according to one embodiment is described with reference to a flowchart FIG. 1.

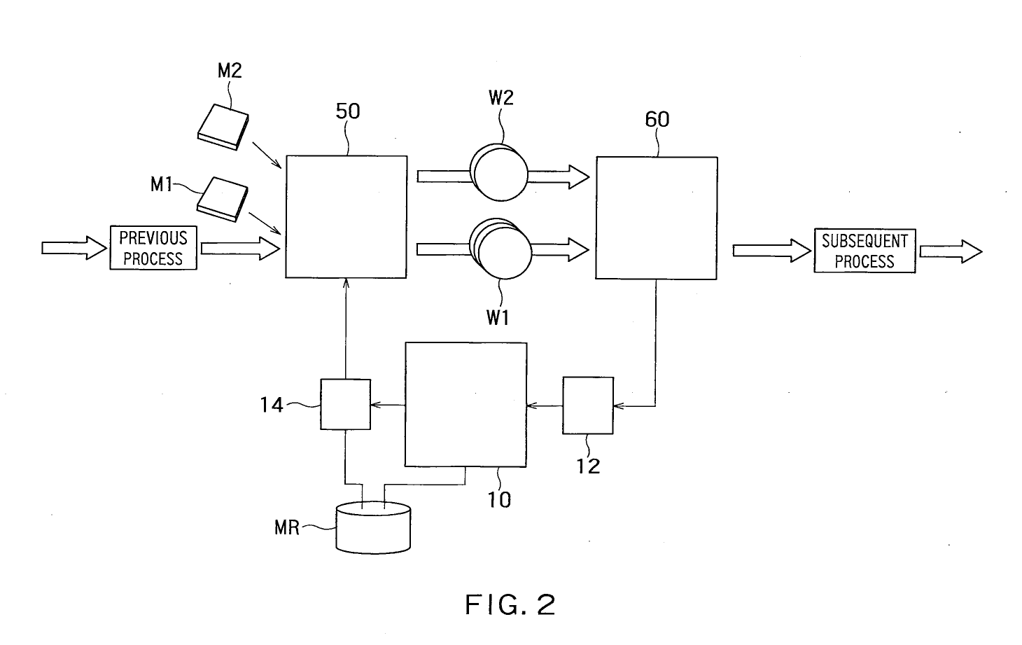

First, in a semiconductor lithographic process, an exposure apparatus (see the reference number 50 in FIG. 2) targeted for focus correction is used to expose a pattern of a product mask onto a resist on a product wafer and thus produce a product wafer (step S1).

The produced product wafer is then introduced into a focus measurement apparatus (see the reference number 60 in FIG. 2), and a defocus amount in the exposure apparatus during exposure is measured (step S2). In the present embodiment, the defocus amount obtained by the measurement of the product wafer corresponds to, for example, a second defocus amount.

A QC wafer is then prepared (step S3). A focus QC mask having a large number (e.g. 101×101) of focus measurement patterns arranged in a shot is created as a QC mask, and an exposure is carried out using this focus QC mask by the exposure apparatus which has illuminated the product mask. As a result, a QC wafer is produced.

The QC wafer is then introduced into the focus measurement apparatus which has been used for the focus measurement in the product wafer, and a defocus amount in the QC wafer is measured (step S4). In the present embodiment, the defocus amount obtained by the measurement of the QC wafer corresponds to, for example, a first defocus amount.

Of all the regions of the QC wafer, a region where no focus measurement patterns are arranged is then interpolated among on the basis of the obtained defocus amount data regarding the QC wafer, and a defocus map of the QC wafer is thereby created. The created defocus map includes the defocus amount obtained by the focus measurement apparatus and the defocus amount obtained by the interpolation. For the creation of the defocus map, each of the defocus amounts are matched with the coordinates of the product wafer for which the defocus amount has been measured in step S2 (step S5).

Since most of the regions on the product wafer are filled with the space for forming device patterns, and exclusive patters intended for measurement can only be created in limited regions such as a calf, the number of focus measurement patterns is also limited. Therefore, regarding defocus tendency in a shot, it is possible to only know rough tendency.

Meanwhile, there is no such limit on the QC mask as that on the product mask, so that as described above, a large number of focus measurement patterns can be arranged. Therefore, it is possible to know high-order defocus tendency in a shot from the QC wafer.

However, no product pattern is formed in the QC wafer. It is therefore impossible to measure the distribution of a deceptive amount specific to the product wafer resulting from the variations in the thickness of a foundation or a resist and the surface height of the resist attributed to steps in a device or a stack structure in a lower layer. Thus, in the present embodiment, the defocus amounts of the QC wafer and the product wafer at the same coordinates in an X, Y plane are compared to find a tendency difference in the wafer surface, and the distribution of the deceptive amount (x, y deceptive amount) is acquired. The deceptive amount matched with the coordinate position in the X, Y plane is hereinafter referred to as a “deceptive component”.

More specifically, the deceptive component resulting from the variations in the thickness of the foundation or the resist and the surface height of the resist is first acquired by calculating the difference between the defocus amount obtained by the measurement of the focus measurement patterns in the product wafer and the defocus amount obtained by the measurement of the focus measurement patterns in the QC wafer (FIG. 1, step S6).

A deceptive component wafer map matched with the coordinates of the QC wafer is then acquired by interpolating, on the basis of the obtained deceptive component, the region where no focus measurement patterns are arranged among the regions of the product wafer (step S7).

Then, a high-order defocus map for reflecting the above interpolated deceptive component in an exposure apparatus control parameter is acquired.

More specifically, the sum of the deceptive component in the deceptive component wafer map acquired in step S7 and the defocus amount of the QC wafer acquired in step S4 is calculated, and a deceptive amount corresponding to the calculation result is canceled from each deceptive component in the deceptive component wafer map. As a result, a high-order defocus map which reflects the variations in the thickness of the foundation or the resist and the surface height of the resist is acquired (step S8). In the present embodiment, data regarding the high-order defocus map corresponds to, for example, high-order defocus correction data.

An optimum exposure apparatus control parameter is calculated by performing a predetermined computation between a focus correction map which is obtained by the exposure apparatus control parameter and the high-order defocus map obtained in step S8 (step S9). The predetermined computation includes, for example, not only the extraction of an exposure apparatus control parameter that minimizes the sum of the absolute value of the difference between the focus correction map and the high-order defocus map, but also the extraction of an exposure apparatus control parameter that minimizes the sum of squares of the difference between the focus correction map and the high-order defocus map.

Finally, the optimum value of the exposure apparatus control parameter obtained in step S9 is fed back to the exposure apparatus (step S10), so that the defocus amount of the succeeding lot can be minimized.

Manufacture with the minimum defocus amount is maintained by periodically repeating the above-described procedure in accordance with the number of manufacture lots for each exposure apparatus recipe, elapsed time and the apparatus maintenance condition.

Regarding the above-mentioned interpolation, for example, linear interpolation or cubic interpolation can be used.

Although the defocus amount of the product wafer is acquired before the measurement of the defocus amount of the QC wafer according to the embodiment described above, this is not a limited order. The defocus amount of the QC wafer may be first measured, and then the defocus amount of the product wafer may be acquired.

According to the focus correction method of at least one embodiment described above, the high-order defocus map in which the deceptive component resulting from the variations in the thickness of the foundation or the resist of the product wafer and the surface height of the resist is reflected in the defocus map of the QC wafer is acquired, and the optimum exposure apparatus control parameter is calculated on the basis of the obtained high-order defocus map to correct focus. Therefore, in the semiconductor lithographic process, focus variations in the product wafer can be reduced.

(2) Focus Correction Apparatus

FIG. 2 is a block diagram showing the general configuration of a focus correction apparatus according to one embodiment. The focus correction apparatus shown in FIG. 2 is an apparatus to enable the focus correction according to the embodiment described above.

As shown in FIG. 2, the focus correction apparatus according to the present embodiment includes an input unit 12, a correction data generating unit 10, a parameter correcting unit 14, and a memory device MR.

The input unit 12 is connected to the external measurement apparatus 60, and functions as an interface for loading the measurement result by the measurement apparatus 60 into the correction data generating unit 10.

The external measurement apparatus 60 receives a product wafer W1 and a QC wafer W2 produced by the external exposure apparatus 50 to measure a defocus amount in the exposure apparatus 50. The exposure apparatus 50 is an exposure apparatus targeted for focus correction in a semiconductor lithographic process, and produces the product wafer W1 using a product mask M1 and also produces the QC wafer using a QC mask M2.

The correction data generating unit 10 processes the measurement result provided from the measurement apparatus 60 to generate high-order focus correction data for the entire wafer surface.

The parameter correcting unit 14 corrects an exposure apparatus control parameter in accordance with the high-order focus correction data and then provides a feedback to the exposure apparatus 50.

Not only various computation programs but also control parameters of the exposure apparatus 50 and the focus correction map are stored in the memory device MR.

The operation of the focus correction apparatus shown in FIG. 2 is as follows.

First, a product wafer which has fished preprocessing is introduced into the exposure apparatus 50 in which a product mask M1 is set, and the pattern of the product mask M1 is transferred to a resist (not shown) on the product wafer to produce a product wafer W1. The product wafer W1 is then introduced into the measurement apparatus 60, a defocus amount due to the exposure apparatus 50 during exposure is measured. The measurement result is input to the correction data generating unit 10 via the input unit 12. In the present embodiment, the defocus amount obtained by the measurement of the product wafer W1 corresponds to, for example, the second defocus amount.

A QC wafer which has fished preprocessing is introduced into the exposure apparatus 50 in which a QC mask M2 is set, and the pattern of the QC mask M2 is transferred to a resist (not shown) on the QC wafer to produce a QC wafer W2. In the QC mask, a large number (e.g. 101×101) of focus measurement patterns are arranged in a shot. The produced QC wafer W2 is introduced into the measurement apparatus 60, and a defocus amount due to the exposure apparatus 50 during exposure is measured. The measurement result is input to the correction data generating unit 10 via the input unit 12. In the present embodiment, the defocus amount obtained by the measurement of the QC wafer W2 corresponds to, for example, the first defocus amount.

The correction data generating unit 10 interpolates a region where no focus measurement patterns are arranged among all the regions of the QC wafer on the basis of the input defocus amount data for the QC wafer W2, and thereby creates a defocus map of the QC wafer. At the same time, the correction data generating unit 10 matches each of the defocus amounts including the defocus amount obtained by the interpolation with the coordinates of the product wafer W1.

The correction data generating unit 10 then calculates a tendency difference between the defocus amount obtained by the measurement of the product wafer W1 and the defocus amount obtained by the measurement of the QC wafer W2, and thereby acquires the deceptive component resulting, from the variations in the thickness of the foundation or the resist and the surface height of the resist.

The correction data generating unit 10 then interpolates the region where no focus measurement patterns are formed among the regions of the product wafer on the basis of the obtained deceptive component, and thereby acquires a deceptive component wafer map matched with the coordinates of the QC wafer.

Furthermore, the correction data generating unit 10 calculates the sum of the deceptive component in the deceptive component wafer map and the defocus amount of the QC wafer, and cancels a deceptive amount corresponding to the calculation result from each deceptive component in the deceptive component wafer map. As a result, a high-order defocus map which reflects the variations in the thickness of the foundation or the resist and the surface height of the resist is acquired. The correction data generating unit 10 sends data regarding the acquired high-order defocus map to the parameter correcting unit 14. In the present embodiment, the data regarding the high-order defocus map corresponds to, for example, the high-order defocus correction data.

The parameter correcting unit 14 draws a focus correction map from the memory device MR, and calculates an optimum exposure apparatus control parameter by performing a predetermined computation between the focus correction map and the high-order defocus map sent from the correction data generating unit 10, and then provides a feedback to the exposure apparatus 50. The computation by the parameter correcting unit 14 includes, for example, not only the extraction of an exposure apparatus control parameter that minimizes the sum of the absolute value of the difference between the focus correction map and the high-order defocus map, but also the extraction of an exposure apparatus control parameter, that minimizes the sum of squares of the difference between the focus correction map and the high-order defocus map.

The focus correction apparatus according to at least one embodiment described above includes the correction data generating unit 10 for acquiring the high-order defocus map in which the deceptive component resulting from the variations in the thickness of the foundation or the resist of the product wafer W1 and the surface height of the resist is further reflected in the defocus map of the QC wafer W2 in which the high-order defocus tendency is reflected, and the parameter correcting unit 14 for calculating the optimum exposure apparatus control parameter on the basis of the high-order defocus map acquired by the correction data generating unit 10. Consequently, in the semiconductor lithographic process, focus variations in the product wafer can be reduced.

(3) Program

While the focus correction using the exclusive focus correction apparatus shown in FIG. 2 has been described in the above embodiment, the series of focus correction described above may be incorporated in a program as a recipe file, and read into and executed by a general-purpose computer which can be connected to the exposure apparatus and the measurement apparatus. This enables the focus correction according to the embodiment described above to be carried out by use of the general-purpose computer.

A series of procedures of the focus correction described above may be incorporated in a program to be executed by a computer, and this program may be stored in a recording medium such as a flexible disk or a CD-ROM and read into and executed by the computer. The recording medium is not limited to a portable medium such as a magnetic disk or an optical disk, and may be a fixed recording medium such as a hard disk drive or a memory. The program incorporating the series of procedures of the focus correction described above may be distributed via a communication line (including wireless communication) such as the Internet. Moreover, the program incorporating the series of procedures of the focus correction described above may be distributed in an encrypted, modulated, or compressed state via a wired line or a wireless line such as the Internet or in such a manner as to be stored in a recording medium.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A focus correction method comprising:
obtaining a first defocus amount by measuring a QC wafer;
obtaining a second defocus amount by measuring a product wafer;
generating high-order focus correction data for an entire wafer surface by interpolating the second defocus amount on the basis of the first defocus amount; and
correcting a focus on the basis of the high-order focus correction data.

2. The method of claim 1,
wherein interpolating the second defocus amount comprises
creating a defocus map of the QC wafer so as to match with coordinates of the product wafer,
acquiring a deceptive component resulting from a variation in the surface height of the product wafer from the defocus map and the second defocus amount, and
interpolating the deceptive component to create a deceptive component wafer map, and
the high-order focus correction data is generated from the deceptive component wafer map and the first defocus amount.

3. A focus correction apparatus comprising:
an input unit configured to input data regarding a first defocus amount and data regarding a second defocus amount, the first defocus amount being obtained by measuring, by an external measurement apparatus, a QC wafer produced by an external exposure apparatus, the second defocus amount being obtained by measuring, by the external measurement apparatus, a product wafer produced by the external exposure apparatus; and
a correction data generating unit configured to interpolate the second defocus amount on the basis of the first defocus amount to generate high-order focus correction data for the entire wafer surface.

4. The apparatus of claim 3, further comprising a parameter correcting unit configured to correct an exposure apparatus control parameter in accordance with the high-order focus correction data and to provide a feedback to the external exposure apparatus.

5. The apparatus of claim 4,
wherein the parameter correcting unit extracts a parameter that minimizes the sum of the absolute value of the difference between a focus correction map obtained by an exposure apparatus control parameter before correction and the high-order focus correction data, and thereby corrects the exposure apparatus control parameter.

6. The apparatus of claim 4,
wherein the parameter correcting unit extracts a parameter that minimizes the sum of squares of the difference between a focus correction map obtained by an exposure apparatus control parameter before correction and the high-order focus correction data, and thereby corrects the exposure apparatus control parameter.

7. A non-transitory computer-readable recording medium containing a program which causes a computer connected to an exposure apparatus and a measurement apparatus to execute a focus correction of the exposure apparatus, the focus correction comprising:
generating high-order focus correction data for an entire wafer surface by interpolating a second defocus amount obtained by measuring a product wafer on the basis of a first defocus amount obtained by measuring a QC wafer; and
correcting a focus on the basis of the high-order focus correction data.

8. The medium of claim 7,
wherein interpolating the second defocus amount comprises
creating a defocus map of the QC wafer so as to match with coordinates of the product wafer,
acquiring a deceptive component resulting from a variation in the surface height of the product wafer from the defocus map and the second defocus amount, and
interpolating the deceptive component to create a deceptive component wafer map, and
the high-order focus correction data is generated from the deceptive component wafer map and the first defocus amount.
